(19) United States
(12) Patent Application Publication
(10) Pub. No.: US 2026/0231687 A1
(43) Pub. Date: Aug. 6, 2026

(54) MONOHYDRIDE PASSIVATION OF HIGH RESISTIVITY SI(111) FOR QUANTUM INFORMATION TECHNOLOGIES

(71) Applicant: NORTHWESTERN UNIVERSITY, Evanston, IL (US)

(72) Inventors: Mark C. Hersam, Wilmette, IL (US); Dominic P. Goronzy, Skokie, IL (US); Carlos G. Torres Castanedo, Chicago, IL (US); Michael J. Bedzyk, Wilmette, IL (US)

(21) Appl. No.: 19/149,874

(22) PCT Filed: Jan. 18, 2024
(86) PCT No.: PCT/US2024/011920

§ 371 Date: Jul. 22, 2025

Related U.S. Application Data
(60) Provisional application No. 63/442,158, filed on Jan. 31, 2023.

(51) Int. Cl. H10N 60/01; G06N 10/40; H10N 60/20; H10N 60/85

(52) U.S. Cl. CPC H10N 60/0156; G06N 10/40; H10N 60/0716; H10N 60/20; H10N 60/85

(57) ABSTRACT

This invention provides an approach that minimizes oxidation and other imperfections at the interface between silicon substrates and superconducting niobium thin films through a wet chemical hydrogen passivation treatment of intrinsic, high resistivity Si(111), which is a substrate suitable for superconducting qubit fabrication.

### CROSS-REFERENCE TO RELATED PATENT APPLICATION

This application claims priority to and the benefit of U.S. Provisional Application Ser. No. 63/442,158, filed Jan. 31, 2023, which is incorporated herein in its entirety by reference.

### STATEMENT AS TO RIGHTS UNDER FEDERALLY-SPONSORED RESEARCH

This invention was made with government support under Grant No. DE-AC02-07CH11359 awarded by the Department of Energy. The government has certain rights in the invention.

### FIELD OF THE INVENTION

The present invention generally relates to material science, particularly to monohydride passivation of high resistivity Si(111) for quantum information technologies.

### BACKGROUND OF THE INVENTION

The background description provided herein is to present the context of the invention generally. The subject matter discussed in the background of the invention section should not be assumed to be prior art merely due to its mention in the background of the invention section. Similarly, a problem mentioned in the background of the invention section or associated with the subject matter of the background of the invention section should not be assumed to have been previously recognized in the prior art. The subject matter in the background of the invention section merely represents different approaches, which in and of themselves may also be inventions. Work of the presently named inventors, to the extent it is described in the background of the invention section, as well as aspects of the description that may not otherwise qualify as prior art at the time of filing, are neither expressly nor impliedly admitted as prior art against the invention.

Superconducting qubits are among the most promising platforms for quantum computing technologies, given their fidelity and scalability. Over the past two decades, the quantum coherence of superconducting qubits has increased by multiple orders of magnitude as a result of improvements in qubit design, fabrication methods, and materials quality. However, the microscopic mechanisms of qubit decoherence are still poorly understood. Among possible sources of decoherence, interfaces and surfaces are believed to host materials imperfections that act as two-level-systems (TLS) that compromise the coherence time of the qubit. While structural and chemical information down to the nanometer scale allows defect identification, measurements of the quasiparticle density of states (DOS) of superconductors provide a fingerprint of local inhomogeneities in electronic properties.

Other forms of silicon surface preparation to reduce the oxide for qubit manufacturing rely on wet chemical etching procedures that do not fully passivate against oxide regrowth, surface treatments like hexamethyldisilazane (HMDS) that contaminate the Nb/Si interface, or ion milling that roughens the surface.

There is a need for an atomically sharp and clean interface that is free of contaminants and oxides in the commercial production of superconducting qubits. Our technology provides a method of silicon surface preparation that results in a Nb on Si film that has enhanced properties for qubit applications in a highly scalable manner.

### SUMMARY OF THE INVENTION

In one aspect, this invention relates to a device for quantum information technologies, comprising at least one hydrogen-passivated Si(111) (H:Si(111)) substrate, wherein Si(111) is a high-resistivity silicon substrate.

In one embodiment, the at least one H:Si(111) substrate possesses a monohydride-terminated silicon surface that is atomically well-defined with atomically flat terraces and sharp atomic steps.

In one embodiment, the device further comprises at least one film of a material grown on the at least one H:Si(111) substrate, wherein the material comprises niobium (Nb), tantalum (Ta), aluminum (Al), titanium nitride (TiN), alloys of nitrides including NbN, TaN, NbTiN and/or TaTiN, and/or metalloid alloys including silicides, germanides and/or borides.

In one embodiment, the at least one film comprises at least one Nb film.

In one embodiment, the atomically-flat, monohydride H:Si(111) substrate yields a smoother and less defective interface between the at least one Nb film and the at least one H:Si(111) substrate.

In one embodiment, the at least one Nb film grown on the at least one H:Si(111) substrate presents more uniform superconducting properties and exhibits less quasiparticle broadening.

In one embodiment, the at least one Nb film has a thickness of about Δ₀ nm that is sufficiently thin to remain sensitive to the Nb/Si interface while minimizing the suppression of the superconducting critical temperature (T_{c}) compared to the bulk Nb value.

In one embodiment, the out-of-plane lattice parameter is strained for the at least one film grown on the at least one H:Si(111) substrate with an expansion of about 1.74%.

In one embodiment, the at least one Nb film grown on the at least one H:Si(111) substrate shows an equivalent granular growth with elongated and randomly oriented grains.

In one embodiment, the root mean square (RMS) roughness is in the order of about 1 nm.

In one embodiment, the tunneling spectrum on Nb—H:Si(111) shows higher coherence peaks and fewer states in the gap than the spectrum for Nb—Si(001).

In one embodiment, the at least one Nb film grown on the H:Si(111) substrate has a reduced superconducting gap compared to a bulk Nb gap.

In one embodiment, the at least one Nb film grown on the at least one H:Si(111) substrate exhibits a spatial variation of the superconducting gap on a submicron scale.

In one embodiment, in the at least one Nb film grown on the at least one H:Si(111) substrate, the superconducting gap is spatially more uniform with the tunneling spectra showing a smaller quasiparticle broadening.

In one embodiment, the at least one Nb film grown on the at least one H:Si(111) substrate has a narrower distribution of gap values and much lower values of Γ/Δ₀, wherein T is the broadening parameter, and Δ₀ is the superconducting gap.

In one embodiment, Δ₀=1.32 meV for the at least one Nb film grown on the at least one H:Si(111) substrate.

In one embodiment, the tunneling spectrum on Nb—H:Si(111) has higher coherence peaks and fewer states in the gap than that on Nb—Si(001).

In one embodiment, the coherence peaks are suppressed at the center of the vortex core on a length scale given by the superconducting coherence length, and low-energy excitation Caroli-de Gennes-Matricon states are absent.

In one embodiment, the nonuniform density of states and the spatial fluctuation of the superconducting order parameter are suggested as a possible source of trapped quasiparticles, which induce qubit decoherence.

In one embodiment, the device is a transmon qubit device.

In another aspect, the invention relates to a method for fabricating a device for quantum information technologies, comprising providing at least one high resistivity silicon Si(111) substrate; and performing hydrogen passivation on the at least one Si(111) substrate to form at least one hydrogen-passivated Si(111) (H:Si(111)) substrate.

In one embodiment, the at least one H:Si(111) substrate possesses a monohydride-terminated silicon surface that is atomically well-defined with atomically flat terraces and sharp atomic steps.

In one embodiment, said performing the hydrogen passivation comprises a sequential treatment with HF and NH₄F.

In one embodiment, said performing the hydrogen passivation further comprises RCA (Radio Corporation of America) cleaning all components prior to HF and NH₄F treatment and extending the Ar-sparging time to at least two hours prior to the beginning of the surface treatment.

In one embodiment, the method further comprises, immediately following the hydrogen passivation procedure, sealing the H:Si(111) substrate in UHP Ar to avoid oxidation of the H:Si(111) surface during transit to a deposition chamber.

In one embodiment, the method further comprises growing at least one thin film of a material on the at least one H:Si(111) substrate in the deposition chamber, wherein the material comprises niobium (Nb), tantalum (Ta), aluminum (Al), titanium nitride (TiN), alloys of nitrides including NbN, TaN, NbTiN and/or TaTiN, and/or metalloid alloys including silicides, germanides and/or borides

In one embodiment, the deposition chamber is a vacuum chamber with a base pressure<10⁻⁸ Torr at room temperature.

In one embodiment, the hydrogen passivation of the at least one Si(111) substrate minimizes oxidation and imperfections at the interface between the at least one H:Si(111) substrate and the at least one Nb thin film.

In one embodiment, the at least one Nb film grown on the at least one H:Si(111) substrate presents more uniform superconducting properties and exhibits less quasiparticle broadening.

In one embodiment, the at least one Nb film has a thickness of about 30-40 nm that is sufficiently thin to remain sensitive to the Nb/Si interface while minimizing the suppression of the superconducting critical temperature (T_{c}) compared to the bulk Nb value.

In one embodiment, the at least one Nb film grown is polycrystalline on the at least one H:Si(111) substrate.

In one embodiment, the out-of-plane lattice parameter is strained for the at least one film grown on the at least one H:Si(111) substrate with an expansion of about 0-3%.

In one embodiment, the at least one Nb film grown on the at least one H:Si(111) substrate shows an equivalent granular growth with elongated and randomly oriented grains.

In one embodiment, the root mean square (RMS) roughness is in the order of about 1 nm.

In one embodiment, the spectrum on Nb—H:Si(111) shows higher coherence peaks and fewer states in the gap than the spectrum for Nb—Si(001).

In one embodiment, the at least one Nb film grown on the H:Si(111) substrate has a reduced superconducting gap compared to a bulk Nb gap.

In one embodiment, the at least one Nb film grown on the at least one H:Si(111) substrate exhibits a spatial variation of the superconducting gap on a submicron scale.

In one embodiment, in the at least one Nb film grown on the at least one H:Si(111) substrate, the superconducting gap is spatially more uniform with the tunneling spectra showing a smaller quasiparticle broadening.

In one embodiment, the at least one Nb film grown on the at least one H:Si(111) substrate has a narrower distribution of gap values and much lower values of Γ/Δ₀, wherein Γ is the broadening parameter, and Δ₀ is the superconducting gap.

In one embodiment, Δ₀=1.32 meV for the at least one Nb film grown on the at least one H:Si(111) substrate.

In one embodiment, the tunneling spectrum on Nb—H:Si(111) has higher coherence peaks and fewer states in the gap than that on Nb—Si(001).

In one embodiment, the coherence peaks are suppressed at the center of the vortex core on a length scale given by the superconducting coherence length, and low-energy excitation Caroli-de Gennes-Matricon states are absent.

These and other aspects of the present invention will become apparent from the following description of the preferred embodiment taken in conjunction with the following drawings, although variations and modifications therein may be affected without departing from the spirit and scope of the novel concepts of the invention.

### BRIEF DESCRIPTION OF THE DRAWINGS

The accompanying drawings illustrate one or more embodiments of the invention and together with the written description, serve to explain the principles of the invention. Wherever possible, the same reference numbers are used throughout the drawings to refer to the same or like elements of an embodiment.

FIG. 1 shows topography images of the Si(001) and H:Si(111) substrates, according to embodiments of the invention. Atomic force microscopy (AFM) images of (panel (a)) Si(001) and (panel (b)) H:Si(111). Scale bars are 500 nm.

FIG. 2 shows topography images of the Nb films, according to embodiments of the invention. Atomic force microscopy (AFM) images of as-grown Δ₀ nm thick Nb films on (panel (a)) Si(001) and (panel (b)) H:Si(111). Scale bars are 250 nm. Scanning tunneling microscopy (STM) topography images acquired on Δ₀ nm thick Nb film grown on (panel (c)) Si(001) and (panel (d)) H:Si(111). The images have been acquired after Ar-ion sputtering and annealing. Scale bars are 80 nm, and the tunneling conditions were I=20 pA and V=0.1 V.

FIG. 3 shows tunneling spectroscopy of Nb films, according to embodiments of the invention. Panel (a): Comparison between spectra acquired on a Δ₀ nm Nb film on Si(001) (red line) at T=1.53K and on H:Si(111) (blue line) at T=1.48K. Panel (b): Experimental curve for Nb/Si(001) with the proximity model fit (red curve) and the BCS curve with coherence peaks at the same energy. The proximity model fit parameters are: Δ₀=1.36 meV, Γ=0.01 meV, α=0.15, β=0.54. The BCS curve has been calculated for Δ₀=0.85 meV, Γ=0, and T=1.53K. Panel (c): Experimental curve for Nb/H: Si(111) compared with the proximity model fit (red curve) and the BCS curve with coherence peaks at the same energy. The proximity model fit parameters are: Δ₀=1.32 meV, Γ=0.001 meV, α=0.084, β=0.49. The BCS curve has been calculated for Δ₀=0.95 meV, Γ=0, and T=1.48K.

FIG. 4 shows spatial variations of the superconducting gap Δ₀ and broadening parameter Γ on Nb films at T=1.5 K, according to embodiments of the invention. The values of the superconducting gap Δ₀ at the surface of the Nb film, just underneath the oxide layer, and the values of the broadening parameter Γ are the output parameters of the proximity fit obtained by fitting a grid of 12× 12 spectra acquired over a scan area of 390 nm. Panels (a) and (b) are the Ao-maps; Panels (c) and (d) are the T-maps obtained for a Nb/Si(001) film and a Nb/H:Si(111) film, respectively. Tunneling conditions were I=60 pA and V=10 mV for all spectra.

FIG. 5 shows tunneling conductance maps acquired at the Fermi energy E_{F} on the Δ₀ nm thick Nb films at T=1.5 K and H=0.15 T showing the Abrikosov vortex lattice, according to embodiments of the invention. Panel (a): Δ₀ nm thick Nb film on Si(001), Panel (b): Δ₀ nm thick Nb on film H:Si(111). Panels (c) and (d): Series of tunneling spectra (dI/dV) acquired across a vortex core along the white lines in panels (a) and (b), respectively. Tunneling conditions were I=60 pA, V=10 mV, and a lock-in modulation V=0.2 mV with a lock-in frequency of 373.1 Hz. Panel (e) and (f): Evolution of the zero bias conductance (ZBC) as a function of position from the vortex core. The ZBC is extracted for each vortex in the images in panels (a) and (b) by performing a radial average except for those vortices close to the edges of the image. The average is then normalized by the ZBC value at the center of the vortex core.

FIG. 6 shows X-ray characterization of Nb films, according to embodiments of the invention. X-ray reflectivity of the Nb film deposited on (panel (a)) Si (001) and (panel (b)) H:Si (111). X-ray diffraction of the Nb film deposited on (panel (c)) Si (001) and (d) H:Si (111). Both measurements were performed in the 2θ/θ configuration.

FIG. 7 shows histograms of the output fit parameters of tunneling spectra, according to embodiments of the invention. Panel (a): Histogram comparison of the fit parameters Δ₀, Panel (b): Γ/Δ₀, Panel (c) α and panel (d) β for N=432 spectra acquired on Nb/Si(001) and N=432 spectra acquired on Nb/Si(111):H.

### DETAILED DESCRIPTION OF THE INVENTION

The invention will now be described more fully hereinafter with reference to the accompanying drawings, in which exemplary embodiments of the invention are shown. However, this invention may be embodied in many different forms and should not be construed as limited to the embodiments set forth herein. Rather, these embodiments are provided so that this specification will be thorough and complete and fully convey the invention's scope to those skilled in the art. Like reference numerals refer to like elements throughout.

The terms used in this specification generally have their ordinary meanings in the art, within the context of the invention, and in the specific context where each term is used. Certain terms used to describe the invention are discussed below, or elsewhere in the specification, to provide additional guidance to the practitioner regarding the description. For convenience, certain terms may be highlighted, for example using italics and/or quotation marks. The use of highlighting has no influence on the scope and meaning of a term; the scope and meaning of a term are the same, in the same context, whether or not it is highlighted. It will be appreciated that same thing can be said in more than one way. Consequently, alternative language and synonyms may be used for any one or more of the terms discussed herein, nor is any special significance to be placed upon whether or not a term is elaborated or discussed herein. Synonyms for certain terms are provided. A recital of one or more synonyms does not exclude the use of other synonyms. The use of examples anywhere in this specification including examples of any terms discussed herein is illustrative only, and in no way limits the scope and meaning of the invention or of any exemplified term. Likewise, the invention is not limited to various embodiments given in this specification.

It will be understood that, as used in the description herein and throughout the claims that follow, the meaning of “a”, “an”, and “the” includes plural reference unless the context clearly dictates otherwise. Also, it will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, or section without departing from the invention's teachings.

Furthermore, relative terms, such as “lower” or “bottom” and “upper” or “top,” may be used herein to describe one element's relationship to another element as illustrated in the figures. It will be understood that relative terms are intended to encompass different orientations of the device in addition to the orientation depicted in the figures. For example, if the device in one of the figures is turned over, elements described as being on the “lower” side of other elements would then be oriented on “upper” sides of the other elements. The exemplary term “lower”, can, therefore, encompasses both an orientation of “lower” and “upper,” depending on the particular orientation of the figure. Similarly, if the device in one of the figures is turned over, elements described as “below” or “beneath” other elements would then be oriented “above” the other elements. Therefore, the exemplary terms “below” or “beneath” can encompass both an orientation of above and below.

It will be further understood that the terms “comprises” and/or “comprising,” or “includes” and/or “including” or “has” and/or “having”, or “carry” and/or “carrying,” or “contain” and/or “containing,” or “involve” and/or “involving, and the like are to be open-ended, i.e., to mean including but not limited to. When used in this specification, they specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and this specification, and will not be interpreted in an idealized or overly formal sense unless expressly so defined herein.

As used in this specification, “around”, “about”, “approximately” or “substantially” shall generally mean within 20 percent, preferably within 10 percent, and more preferably within 5 percent of a given value or range. Numerical quantities given herein are approximate, meaning that the term “around”, “about”, “approximately” or “substantially” can be inferred if not expressly stated.

As used in this specification, the phrase “at least one of A, B, and C” should be construed to mean a logical (A or B or C), using a non-exclusive logical OR. As used herein, the term “and/or” includes any and all combinations of one or more of the associated listed items.

The description below is merely illustrative in nature and is in no way intended to limit the invention, its application, or uses. The broad teachings of the invention can be implemented in a variety of forms. Therefore, while this invention includes particular examples, the true scope of the invention should not be so limited since other modifications will become apparent upon a study of the drawings, the specification, and the following claims. For purposes of clarity, the same reference numbers will be used in the drawings to identify similar elements. It should be understood that one or more steps within a method may be executed in a different order (or concurrently) without altering the principles of the invention.

Achieving fault tolerant quantum computing requires both scaling in number of qubits and increasing the coherence time of qubits. Superconducting qubits are a promising platform for fault tolerant quantum computing, as their production is readily scalable, although the coherence time in this qubit technology is not yet sufficiently long for most practical applications. Nonuniformity in the density of states in superconducting materials and spatial fluctuations in the superconducting order parameter have been identified as potential sources of trapped quasiparticles, which result in decoherence and information loss in superconducting qubits. Contaminants and oxides at the interface between the substrate and superconducting metal have been suggested as the underlying sources of this decoherence pathway.

To address this key issue in quantum computing technology, this invention provides an approach that minimizes oxidation and other imperfections at the interface between silicon substrates and superconducting niobium thin films through a wet chemical hydrogen passivation treatment of intrinsic, high resistivity Si(111), which is a substrate suitable for superconducting qubit fabrication. In superconducting niobium films grown on the resulting atomically flat, monohydride H:Si(111) substrates, the superconducting gap is spatially more uniform with the corresponding tunneling spectra showing reduced quasiparticle broadening in comparison to niobium films grown on standard Si(001) substrates that are currently used for state-of-the-art superconducting qubits in industry. By reducing sources of decoherence, this invention establishes atomically flat, monohydride H:Si(111) as an ideal substrate for next-generation quantum information technologies.

In one aspect, this invention relates to a device for quantum information technologies, comprising at least one hydrogen-passivated Si(111) (H:Si(111)) substrate, wherein Si(111) is a high-resistivity silicon substrate.

In one embodiment, the at least one H:Si(111) substrate possesses a monohydride terminated silicon surface that is atomically well-defined with atomically flat terraces and sharp atomic steps.

In one embodiment, the device further comprises at least one niobium (Nb) film grown on the at least one H:Si(111) substrate.

One should be appreciated that this can be applied to all materials deposited on Si(111) by physical vapor deposition (PVD) methods. Specifically, for quantum information system (QIS) applications, such relevant materials include tantalum (Ta), aluminum (Al), titanium nitride (TiN), alloys of nitrides including NbN, TaN, NbTiN and/or TaTiN, and/or metalloid alloys including silicides, germanides and/or borides.

In one embodiment, the atomically-flat, monohydride H:Si(111) substrate yields a smoother and less defective interface between the at least one Nb film and the at least one H:Si(111) substrate.

In one embodiment, the at least one Nb film grown on the at least one H:Si(111) substrate presents more uniform superconducting properties and exhibits less quasiparticle broadening.

In one embodiment, the at least one Nb film has a thickness of about 30-40 nm that is sufficiently thin to remain sensitive to the Nb/Si interface while minimizing the suppression of the superconducting critical temperature (T_{c}) compared to the bulk Nb value.

In one embodiment, the at least one Nb thin film is polycrystalline on the at least one H:Si(111) substrate.

In one embodiment, the out-of-plane lattice parameter is strained for the at least one film grown on the at least one H:Si(111) substrate with an expansion of about 0-3%.

In one embodiment, the at least one Nb film grown on the at least one H:Si(111) substrate shows an equivalent granular growth with elongated and randomly oriented grains.

In one embodiment, the root mean square (RMS) roughness is in the order of about 1 nm.

In one embodiment, the spectrum on Nb—H:Si(111) shows higher coherence peaks and fewer states in the gap than the spectrum for Nb—Si(001).

In one embodiment, the at least one Nb film grown on the H:Si(111) substrate has a reduced superconducting gap compared to a bulk Nb gap.

In one embodiment, the at least one Nb film grown on the at least one H:Si(111) substrate exhibits a spatial variation of the superconducting gap on a submicron scale.

In one embodiment, in the at least one Nb film grown on the at least one H:Si(111) substrate, the superconducting gap is spatially more uniform with the tunneling spectra showing a smaller quasiparticle broadening.

In one embodiment, the at least one Nb film grown on the at least one H:Si(111) substrate has a narrower distribution of gap values and much lower values of Γ/Δ₀, wherein Γ is the broadening parameter, and Δ₀ is the superconducting gap.

In one embodiment, Δ₀=1.32 meV for the at least one Nb film grown on the at least one H:Si(111) substrate.

In one embodiment, the tunneling spectrum on Nb—H:Si (111) has higher coherence peaks and fewer states in the gap than that on Nb—Si(001).

In one embodiment, the coherence peaks are suppressed at the center of the vortex core on a length scale given by the superconducting coherence length, and low-energy excitation Caroli-de Gennes-Matricon states are absent.

In one embodiment, the nonuniform density of states and the spatial fluctuation of the superconducting order parameter are suggested as a possible source of trapped quasiparticles, which induce qubit decoherence.

In one embodiment, the device is a transmon qubit device.

In another aspect, the invention relates to a method for fabricating a device for quantum information technologies, comprising providing at least one high resistivity silicon Si(111) substrate; and performing hydrogen passivation on the at least one Si(111) substrate to form at least one hydrogen-passivated Si(111) (H:Si(111)) substrate.

In one embodiment, the at least one H:Si(111) substrate possesses a monohydride terminated silicon surface that is atomically well-defined with atomically flat terraces and sharp atomic steps.

In one embodiment, said performing the hydrogen passivation comprises a sequential treatment with HF and NH₄F.

In one embodiment, said performing the hydrogen passivation further comprises RCA cleaning all components prior to HF and NH₄F treatment and extending the Ar-sparging time to at least two hours prior to the beginning of the surface treatment.

In one embodiment, the method further comprises, immediately following the hydrogen passivation procedure, sealing the H:Si(111) substrate in UHP Ar to avoid oxidation of the H:Si(111) surface during transit to a deposition chamber.

In one embodiment, the method further comprises growing at least one thin film of a material on the at least one H:Si(111) substrate in the deposition chamber, wherein the material comprises niobium (Nb), tantalum (Ta), aluminum (Al), titanium nitride (TiN), alloys of nitrides including NbN, TaN, NbTiN and/or TaTiN, and/or metalloid alloys including silicides, germanides and/or borides.

In one embodiment, the deposition chamber is a vacuum chamber with a base pressure<10⁻⁸ Torr at room temperature.

In one embodiment, the hydrogen passivation of the at least one Si(111) substrate minimizes oxidation and imperfections at the interface between the at least one H:Si(111) substrate and the at least one Nb thin film.

In one embodiment, the at least one Nb film grown on the at least one H:Si(111) substrate presents more uniform superconducting properties and exhibit less quasiparticle broadening.

In one embodiment, the at least one Nb film has a thickness of about 30-40 nm that is sufficiently thin to remain sensitive to the Nb/Si interface while minimizing the suppression of the superconducting critical temperature (T_{c}) compared to the bulk Nb value.

In one embodiment, the out-of-plane lattice parameter is strained for the at least one film grown on the at least one H:Si(111) substrate with an expansion of about 0-3%.

In one embodiment, the at least one Nb film grown on the at least one H:Si(111) substrate shows an equivalent granular growth with elongated and randomly oriented grains.

In one embodiment, the root mean square (RMS) roughness is in the order of about 1 nm.

In one embodiment, the spectrum on Nb—H:Si(111) shows higher coherence peaks and fewer states in the gap than the spectrum for Nb—Si(001).

In one embodiment, the at least one Nb film grown on the H:Si(111) substrate has a reduced superconducting gap compared to a bulk Nb gap.

In one embodiment, the at least one Nb film grown on the at least one H:Si(111) substrate exhibits a spatial variation of the superconducting gap on a submicron scale.

In one embodiment, in the at least one Nb film grown on the at least one H:Si(111) substrate, the superconducting gap is spatially more uniform with the tunneling spectra showing a smaller quasiparticle broadening.

In one embodiment, the at least one Nb film grown on the at least one H:Si(111) substrate has a narrower distribution of gap values and much lower values of Γ/Δ₀, wherein Γ is the broadening parameter, and Δ₀ is the superconducting gap.

In one embodiment, 40=1.32 meV for the at least one Nb film grown on the at least one H:Si(111) substrate.

In one embodiment, the tunneling spectrum on Nb—H:Si(111) has higher coherence peaks and fewer states in the gap than that on Nb—Si(001).

In one embodiment, the coherence peaks are suppressed at the center of the vortex core on a length scale given by the superconducting coherence length, and low-energy excitation Caroli-de Gennes-Matricon states are absent.

Among other things, the invention has at least the following advantages over the prior art.

Silicon oxides form readily on silicon substrates in ambient conditions. This amorphous oxide is known to host sources of loss for quantum coherence. Conventional fluoride-based wet chemical etching can remove the native oxide on silicon and has been used for substrate preparation in many fields, although the silicon will immediately begin to reform the oxide in ambient conditions. The approach according to the invention forms a passivating monohydride termination on Si(111) that prevents immediate reoxidation, providing stability for at least several hours in ambient air. The passivation method is optimized for intrinsic, high-resistivity silicon, which is required for qubit fabrication.

In the current field of niobium on silicon qubit fabrication, methods for preparing silicon surfaces preceding niobium deposition include treatment with hexamethyldisilazane (HMDS) or ion milling. The HMDS treatment results in a silicon surface that is terminated with oxy-hydrocarbons and is a potential source of contamination at the Nb/Si interface. In the case of ion milling, the surface of silicon is amorphized and roughened. The wet chemical hydrogen passivation of Si(111) produces a monohydride terminated silicon surface that is atomically well-defined with atomically flat terraces and sharp atomic steps.

In comparison to Nb films on Si(001), where the silicon surface is prepared with a HMDS procedure, Nb films on H:Si(111) demonstrate a more spatially uniform superconducting gap and smaller quasiparticle broadening, which are features that improve qubit coherence.

The invention in certain aspects, provides a method of silicon surface preparation that results in a Nb on Si film that has enhanced properties for qubit applications in a highly scalable manner, which may find applications in superconducting qubits, quantum computers, quantum sensing, quantum communication, quantum transduction, low-loss silicon substrates, interface control in thin film deposition, silicon functionalization and patterning, and so on.

These and other aspects of the invention are further described below. Without intent to limit the scope of the invention, exemplary instruments, apparatus, methods, and their related results according to the embodiments of the invention are given below. Note that titles or subtitles may be used in the examples for convenience of a reader, which in no way should limit the scope of the invention. Moreover, certain theories are proposed and disclosed herein; however, in no way they, whether they are right or wrong, should limit the scope of the invention so long as the invention is practiced according to the invention without regard for any particular theory or scheme of action.

### Example: Scanning Tunneling Microscopy and Spectroscopy Characterization of Nb Films for Superconducting Qubits

Despite a tremendous effort to improve the performance of superconducting qubits in recent years, sources of decoherence are still not well understood. However, surfaces and interfaces are believed to play a significant role. Since Nb superconducting thin films are critical components of superconducting qubits, Nb/substrate and Nb/air interfaces are likely culprits in contributing to decoherence and ultimately limiting the performance of quantum computing technologies.

In this exemplary study, we investigate the Nb/substrate interface by studying the effect of hydrogen-passivated H:Si(111) substrates on the local superconducting properties of ~Δ₀ nm thick Nb films compared to Nb films grown on typical Si(001) substrates. Specifically, low-temperature scanning tunneling microscopy and spectroscopy are employed to compare nanoscale material properties. The atomically-flat, monohydride H:Si(111) substrates yield a smoother and less defective interface with the Nb film. Correspondingly, the Nb films grown on H:Si(111) substrates present more uniform superconducting properties and exhibit less quasiparticle broadening.

Tunneling spectroscopy provides fundamental insight into the nature of superconductivity and reveals both the superconducting gap and broadening of the quasiparticle density of states (DOS) in the tunneling spectrum dI/dV vs. V of a superconducting junction. Scanning tunneling microscopy and spectroscopy (STM/STS) further allow for the spatial mapping of the local DOS and changes in superconducting properties across the sample surface.

In this example, we use low-temperature STM/STS to investigate the local electronic properties of Nb films used in transmon qubit devices with a particular focus on the effect of the substrate-superconductor interface on the local electronic properties of the films. The Nb films used in this example were grown on Si(001) substrates (a commonly used substrate for transmon qubits) or on hydrogen-passivated Si(111) (H:Si(111)) substrates. The monohydride passivation of H:Si(111) prevents the reformation of the silicon native oxide and results in a surface with atomically flat terraces.

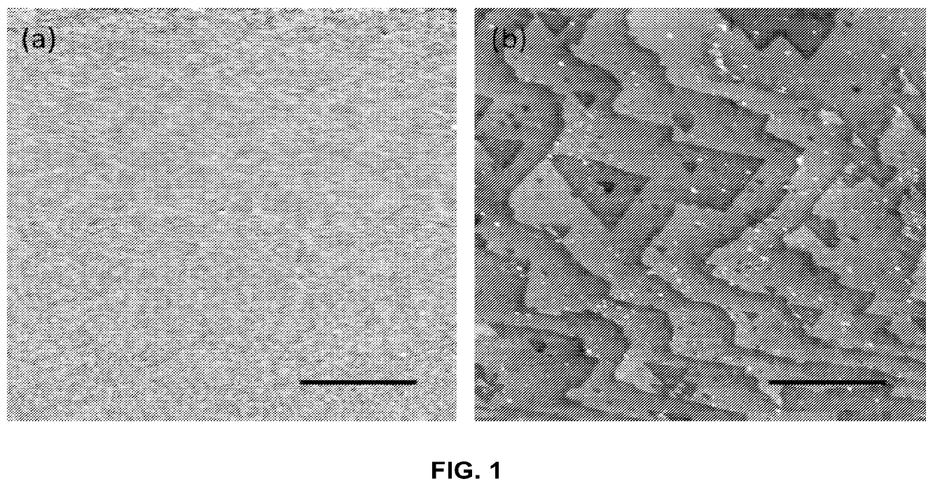

The Nb thin films were grown by High Power Impulse Magnetron Sputtering (HiPIMS) in a vacuum chamber with a base pressure<10⁻⁸ Torr at room temperature. Initially, both the Si(001) and Si(111) substrates undergo standard RCA (Radio Corporation of America) surface cleaning. Before Nb deposition, the Si(001) substrate was further treated with hexamethyldisilazane (HDMS) to create a hydrophobic surface. For the Si(111) substrate, hydrogen passivation was performed via sequential treatment with HF and NH₄F by modifying a previously reported procedure (R. Basu, J.-C. Lin, C.-Y. Kim, M. J. Schmitz, N. L. Yoder, J. A. Kellar, M. J. Bedzyk, and M. C. Hersam, Structural Characterization of 4-Bromostyrene Self-Assembled Monolayers on Si(111), Langmuir 23, 1905 (2007)). These modifications included RCA cleaning all labware prior to HF and NH₄F treatment and extending the Ar-sparging time to at least two hours prior to the beginning of the surface treatment. Immediately following this hydrogen passivation procedure, the H:Si(111) substrate was sealed in ultra high purity (UHP, typically defined as 99.999% purity) Ar to avoid oxidation of the H:Si(111) surface during transit to the Nb deposition chamber. FIG. 1 shows atomic force microscopy (AFM) images of the two substrates used for this study, highlighting the differences in surface morphology. Most notably, the H:Si(111) surface possesses atomically flat terraces with clearly defined step edges.

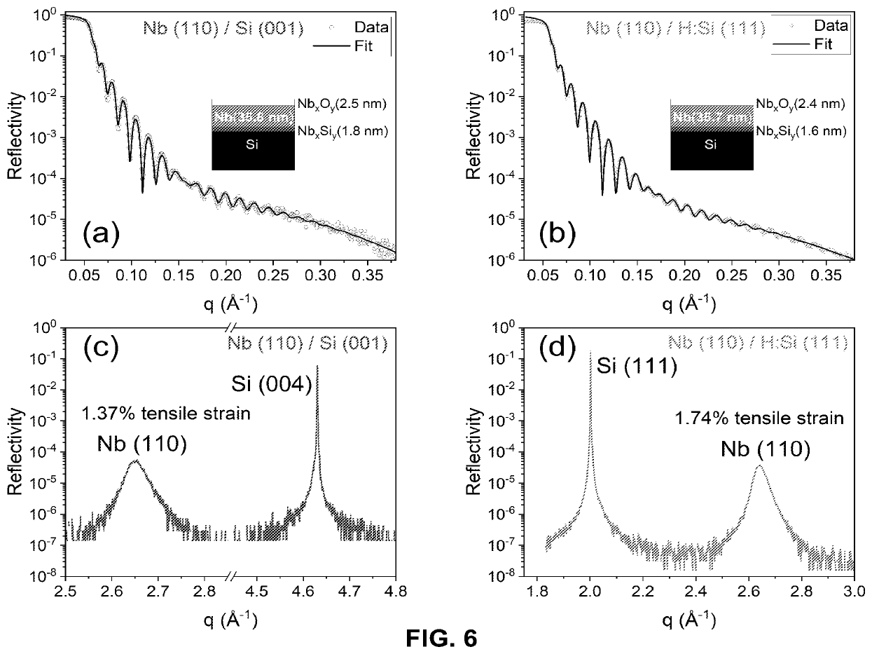

The about Δ₀ nm thickness of the Nb films is sufficiently thin to remain sensitive to the Nb/Si interface while minimizing the suppression of the superconducting critical temperature (T_{c}) compared to the bulk Nb value. In particular, the Δ₀ nm-thick Nb films grown on Si(001) show a superconducting critical temperature T_{c}=8.72 K. X-ray reflectivity experiments show that both films have the same thickness and approximately the same Nb native oxide thickness. X-ray diffraction experiments further reveal that the out-of-plane lattice parameter is strained for films grown on both substrates with an expansion of 1.37% in the case of films grown on Si(001) and 1.74% for films grown on H:Si(111) (FIG. 6). Additionally, the Nb crystallite grain size is 13-14 nm for both samples as extracted from the X-ray data using the Scherrer equation.

Low-temperature STM and STS measurements were performed at 1.5 K, using a Unisoku ultrahigh vacuum STM system equipped with a 9 T superconducting magnet and a base pressure of 10⁻¹¹ Torr. Pt—Ir tips were used in all experiments and were confirmed to be atomically sharp on a gold surface before imaging the Nb thin films.

Nb has a high affinity for oxygen, which causes the Nb superconducting transition temperature to drop by approximately 1 K per atomic percent of oxygen impurity. In addition, Nb thin films following ambient exposure possess an insulating niobium pentoxide (Nb₂O₅) top layer. Therefore, to perform tunneling spectroscopy of the underlying Nb film, the top insulating oxide layer must first be removed. Complete removal of all Nb oxides, including NbO, is only achieved by annealing in ultrahigh vacuum at temperatures higher than 2000° C., which cannot be performed in the presence of the Si substrate due to intermixing and silicide formation with Nb. However, annealing at lower temperatures reduces Nb₂O₅ to either NbO₂ or NbO. Additionally, Nb₂O₅ can be reduced to NbO by Ar-ion sputtering. Consequently, we performed Ar-ion sputtering and subsequent 30-minute annealing at 300° C. before STM measurements. The sputtering and annealing were performed in the preparation chamber attached to the STM with a base pressure of 10⁻¹¹ Torr. The Ar (purity: 99.999%) sputter conditions included a partial pressure of 10⁻⁵ Torr with an energy of 1 keV for 25 minutes. With an estimated oxide removal rate of 0.27 nm/min, this process yields a metallic top surface suitable for STM studies. Tunneling spectroscopy of the resulting Nb/NbO bilayer allows probing of the local quasiparticle density of states (DOS) of the Nb surface just below the metallic oxide, thus providing information about the local superconducting gap and quasiparticle broadening as well as the spatial uniformity of these properties.

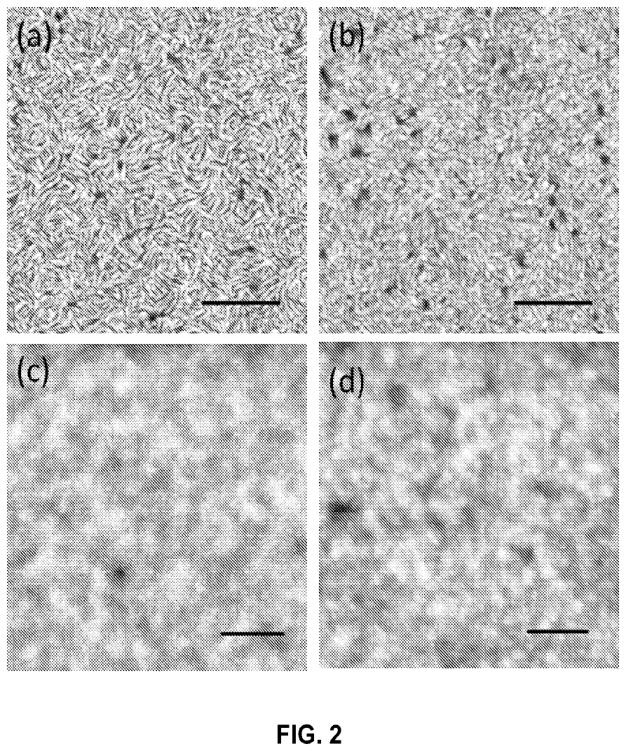

In panels (a) and (b) of FIG. 2, atomic force microscopy (AFM) images of the as-grown Nb films on the Si(001) and H:Si (111) substrates show an equivalent granular growth with elongated and randomly oriented grains. The root mean square (RMS) roughness calculated from AFM images is less than 1 nm in both cases. The Nb thickness of both films is 35.7 nm with an underlying interfacial NbₓSi_{y} layer of 1.7 nm thickness and a top NbₓO_{y} layer of 2.4 nm thickness (FIG. 6). The Nb films are also textured in the (110) orientation (FIG. 6). No epitaxy is observed due to the significant lattice mismatch between Si and Nb. Both films are under tensile strain at levels of about 1.4% and about 1.7% for the Si(001) and H:Si(111) substrates, respectively. The low-temperature STM topographic images acquired after the films have been processed in UHV with Ar-ion sputtering and annealing are shown in panels (c) and (d) of FIG. 2. The surface morphology in both cases changes with the surface processing. However, the RMS roughness remains on the order of 1 nm.

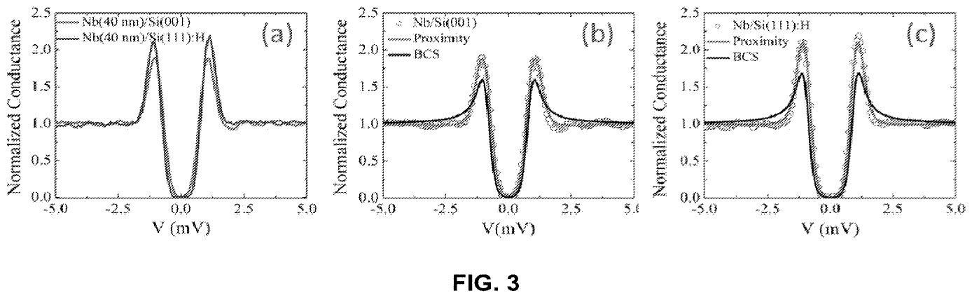

Panel (a) of FIG. 3 shows typical tunneling spectra acquired on the two types of films. The spectrum on Nb—H:Si(111) shows higher coherence peaks and fewer states in the gap than the spectrum for Nb—Si(001). The fits of these experimental tunneling spectra are shown in panels (b) and (c) of FIG. 3 for the films on Si(001) and H:Si(111), respectively. The experimental curves for both cases cannot be reproduced by a simple Bardeen-Cooper-Schrieffer (BCS)-DOS model. Indeed, the BCS curve (black line) with peak position energy at the same value as the experimental curves shows lower coherence peak height and does not fit the sub-gap region well. The experimental curves present coherence peaks higher than those of the BCS model and an undershoot at energies just higher than the energy gap compared to the BCS model. Both features are fingerprints of the superconducting proximity effect. These tunneling spectra were thus analyzed using the proximity model described in Kubo and Gurevich (red line). This model describes a proximity-coupled dirty normal layer (metallic oxide, N in the following) on a bulk superconductor (Nb film, S in the following) using the Usadel equation framework. The quasiparticle density of states measured by the STM across the normal oxide layer is determined by a set of equations described by Lechner et al. The output of the fitting procedure allows for determination of the gap value at the superconductor side of the S—N bilayer, and the parameter Γ, which accounts for the finite lifetime of the Cooper pairs, smears the DOS spectrum and leads to a finite spectral intensity at subgap energies. Furthermore, two additional dimensionless parameters are related to the thickness of the N layer (a) and the transparency of the barrier between the S and N layers (β):

$$α = \frac{{N}_{n}}{{N}_{S}} \frac{d}{{ξ}_{S}} , β = \frac{4 {e}^{2}}{ℏ} {R}_{B} {N}_{n} Δ d .$$

Here, Nₙ and N_{S} are the normal densities of states in N and S, ξₙ=\sqrt{Dₙ/2Δ} and ξ_{S}=\sqrt{D_{S}/2Δ} are the respective coherence lengths, and R_{B} is the contact resistance. The parameters α and β are related to properties of the interface, which can change locally and depend on the native oxide surface and on the specific surface processing. The proximity model can reproduce all of the above spectroscopic features of the experimental curves presented in panels (b) and (c) of FIG. 3. The gap values obtained by the proximity model fit for the curves in panels (b) and (c) of FIG. 3 are very similar for the two films—i.e., Δ₀=1.36 meV for the Nb film on Si(001) and Δ₀=1.32 meV for the Nb film on H:Si(111). These values are lower than bulk Nb but are consistent with the lower T_{c} reported for the Δ₀ nm Nb film on Si(001). More importantly, the parameter Γ varies significantly between the two curves, with the films grown on Si(001) being an order of magnitude higher (Γ=0.01 meV) than the films grown on H:Si(111) (Γ=0.001 meV). This parameter is associated with DOS broadening, which has been attributed to different microscopic origins and is expected to impact qubit coherence lifetime.

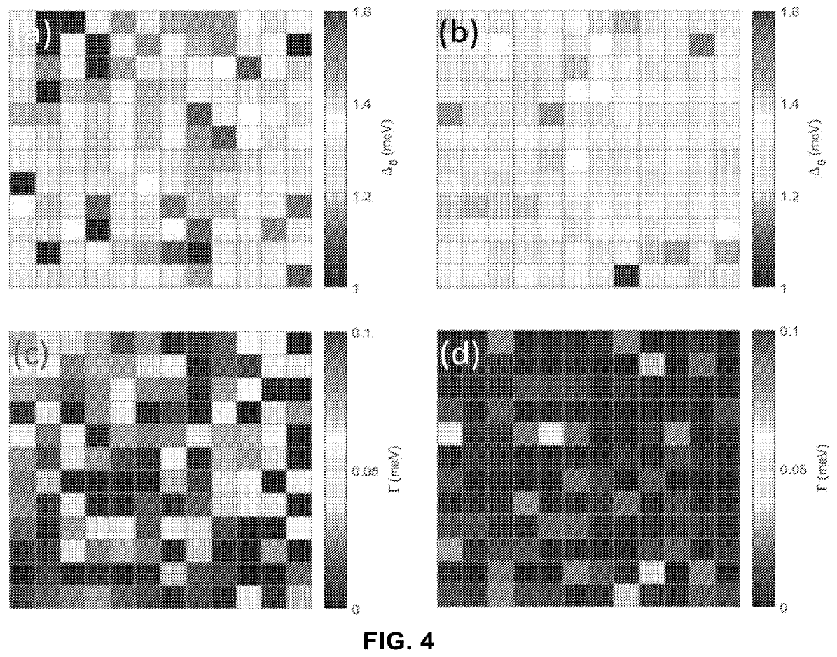

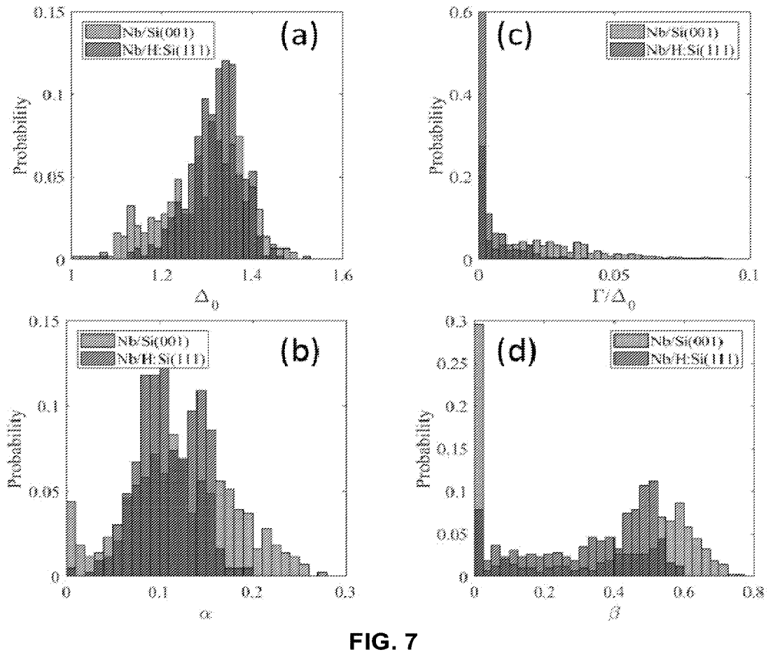

Tunneling spectra were acquired at different locations on the films by measuring grids of 12× 12 dI/dV vs. V spectra over areas of about 390 nm×390 nm. Grids were acquired at locations separated by several tens to hundreds of microns to probe different regions of the sample. These spectra were analyzed with the proximity model. The histograms reporting the spread of the fit parameters over the sample show that both films exhibit a distribution of superconducting gap values. However, while the average value of the gap is similar for the two types of films, the Nb film grown on H:Si (111) shows a narrower distribution of gap values and much lower values of Γ/Δ₀, with similar distributions for the values α and β (FIG. 7). In FIG. 4, the spatial variations acquired on a typical region of 390 nm are reported. Panels (a) and (b) of FIG. 4 show the superconducting gap maps obtained on Nb/Si(001) and Nb/H:Si(111), respectively. Panels (c) and (d) of FIG. 4 show the map of the corresponding broadening parameter Γ obtained by the proximity fit. While both the Δ₀ and Γ maps present spatial variations on both samples, the Nb/H:Si(111) sample is more uniform (panels (b) and (d) of FIG. 4). The α parameter obtained by the proximity fit of the tunneling spectra has a similar distribution and mean value for the Nb/Si(001) and Nb/H:Si(111) films (panel (c) of FIG. 7), suggesting a similar thickness of the normal layer for both films. The average value of β, which is proportional to the N—S contact resistance, R_{B}, is similar for the two types of samples but with a different distribution. As follows from panel (d) of FIG. 7, the Nb/H:Si(111) shows a distribution with lower values of β, indicating a lower contact resistance and surface oxidation.

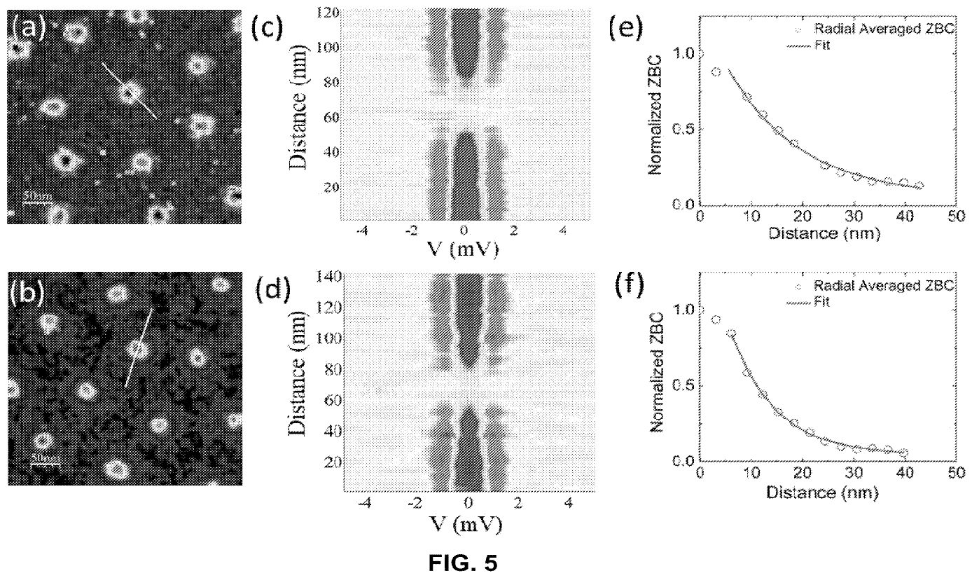

To further study the superconducting properties in these films, we investigated the effect of a magnetic field. We estimated the value of the coherence length ξ from the electronic structure around a magnetic vortex core. In the presence of an applied magnetic field, Abrikosov vortices can penetrate into the sample and modify the local quasiparticle DOS. Mapping these spatial variations with the STM allows direct visualization of the Abrikosov vortex lattice. Panels (a) and (b) of FIG. 5 show the zero-bias conductance (ZBC) map—i.e., the differential conductance at the Fermi level Er. These maps reveal the vortex lattice imaged on Nb/(Si(001) and Nb/H:Si(111) in the presence of a magnetic field H=0.15 T applied perpendicular to the film surface. In both cases, a slightly distorted triangular lattice is observed with vortex-vortex distance in agreement with theoretical predictions. The spatial evolution of the tunneling spectra across a vortex core is reported in the intensity plot of dI/dV ( [symbol] , E) in panels (c) and (d) of FIG. 5. This evolution shows the suppression of the coherence peaks at the center of the vortex core on a length scale given by the superconducting coherence length and the absence of low-energy excitation Caroli-de Gennes-Matricon states predicted in the case of clean superconductors. On the other hand, in dirty superconductors, where the superconducting coherence length ξ is larger than the mean free path l, these core states are broadened by the scattering, ultimately resulting in a flat density of states.

The superconducting coherence length can be evaluated by calculating the azimuthal average of the zero-bias conductance of each vortex in the conductance maps, as shown in panels (a) and (b) of FIG. 5 (except those close to the border of the image). To extract the coherence length, we fit this spatial dependence of the zero-bias conductance, excluding the center of the vortex, with an exponential decay of the form: G=G₀+Aexp (−r/ξ). Here G₀ is the conductance (dI/dV) far from the vortices, A is a constant, and r is the distance from the vortex core center. The result of the average, together with the fit, is reported in panels (e) and (f) of FIG. 5. The obtained values of the superconducting coherence length are ξ≈13 nm and ξ≈10 nm for the Nb/Si(001) and Nb/Si(111) samples, respectively. These values are much smaller than the bulk Nb value of ξ≈38 nm, indicating that the superconductor underneath the metallic oxide layer is in a moderately dirty limit in both samples. Using these values of ξ in the Ginzburg-Landau expression for the upper critical field B_{c2}=Φ₀/2πξ², we obtain B_{c2}=1.95 T for the Nb/Si(001) sample and B_{c2}=3.3 T for the Nb/Si(111) sample. It is worth noting that the presence of a thin normal layer on top of the superconductor affects the size of the vortex core as measured by STM, which appears larger than the Abrikosov vortex cores in the superconductor. This effect is related to the effective coherence length in the normal region.

In summary, we investigated the role of the substrate on the local superconducting properties of Δ₀ nm thick Nb films grown on Si(001) and H:Si(111) for transmon qubit fabrication. We found that both films have a reduced superconducting gap compared to the bulk Nb gap. Furthermore, both films exhibit a spatial variation of the superconducting gap on a submicron scale. However, in the Nb films grown on H:Si(111), the superconducting gap is spatially more uniform with the tunneling spectra showing a smaller quasiparticle broadening. The nonuniform density of states and the spatial fluctuation of the superconducting order parameter have been suggested as a possible source of trapped quasiparticles, which can induce qubit decoherence. Therefore, strategies that can mitigate these spatial variations are timely.

Furthermore, recent measurements of the low-temperature loss tangent of Si substrates show values that are one order of magnitude larger than previously thought, which may be partially attributed to the native oxide on Si. The ability to minimize oxidation and achieve an atomically well-defined and passivated Si surface while preserving the superconducting properties of the Nb film hold promise for addressing this source of decoherence.

The foregoing description of the exemplary embodiments of the invention has been presented only for the purposes of illustration and description, and is not intended to be exhaustive or to limit the invention to the precise forms disclosed. Many modifications and variations are possible in light of the above teaching.

The embodiments were chosen and described to explain the principles of the invention and their practical application to enable others skilled in the art to utilize the invention and various embodiments and with various modifications suited to the particular use contemplated. Alternative embodiments will become apparent to those skilled in the art to which the invention pertains without departing from its spirit and scope. Accordingly, the scope of the invention is defined by the appended claims rather than the foregoing description and the exemplary embodiments described therein.

Some references, which may include patents, patent applications, and various publications, are cited and discussed in the description of this invention. The citation and/or discussion of such references is provided merely to clarify the description of the invention and is not an admission that any such reference is “prior art” to the invention described herein. All references cited and discussed in this specification are incorporated herein by reference in their entireties and to the same extent as if each reference was individually incorporated by reference.

### LIST OF REFERENCES

[1]. M. Kjaergaard, M. E. Schwartz, J. Braumüller, P. Krantz, J. I.-J. Wang, S. Gustavsson, and W. D. Oliver, Superconducting Qubits: Current State of Play, Annual Review of Condensed Matter Physics 11, 369 (2020).
[2]. C. Müller, J. H. Cole, and J. Lisenfeld, Towards Understanding Two-Level-Systems in Amorphous Solids: Insights from Quantum Circuits, Rep. Prog. Phys. 82, 124501 (2019).
[3]. A. A. Murthy, J. Lee, C. Kopas, M. J. Reagor, A. P. McFadden, D. P. Pappas, M. Checchin, A. Grassellino, and A. Romanenko, TOF-SIMS Analysis of Decoherence Sources in Superconducting Qubits, Appl. Phys. Lett. 120, 044002 (2022).
[4]. A. A. Murthy et al., Developing a Chemical and Structural Understanding of the Surface Oxide in a Niobium Superconducting Qubit, arXiv: 2203.08710.
[5]. I. Giaever, Energy Gap in Superconductors Measured by Electron Tunneling, Phys. Rev. Lett. 5, 147 (1960).
[6]. I. Giaever, Electron Tunneling Between Two Superconductors, Phys. Rev. Lett. 5, 464 (1960).
[7]. R. C. Dynes, V. Narayanamurti, and J. P. Garno, Direct Measurement of Quasiparticle-Lifetime Broadening in a Strong-Coupled Superconductor, Physical Review Letters 41, 1509 (1978).
[8]. W. Kern, The Evolution of Silicon Wafer Cleaning Technology, J. Electrochem. Soc. 137, 1887 (1990).
[9]. A. Nersisyan et al., Manufacturing Low Dissipation Superconducting Quantum Processors, in 2019 IEEE International Electron Devices Meeting (IEDM) (2019), p. 31.1.1-31.1.4.
[10]. R. Basu, J.-C. Lin, C.-Y. Kim, M. J. Schmitz, N. L. Yoder, J. A. Kellar, M. J. Bedzyk, and M. C. Hersam, Structural Characterization of 4-Bromostyrene Self-Assembled Monolayers on Si(111), Langmuir 23, 1905 (2007).
[11]. K. M. Ryan et al., Characterization of Nb Films for Superconducting Qubits Using Phase Boundary Measurements, arXiv: 2207.13125.
[12]. A. L. Patterson, The Scherrer Formula for X-Ray Particle Size Determination, Phys. Rev. 56, 978 (1939).
[13]. C. C. Koch, J. O. Scarbrough, and D. M. Kroeger, Effects of Interstitial Oxygen on the Superconductivity of Niobium, Phys. Rev. B 9, 888 (1974).
[14]. B. An, S. Fukuyama, K. Yokogawa, and M. Yoshimura, Surface Structures of Clean and Oxidized Nb(100) by LEED, AES, and STM, Phys. Rev. B 68, 115423 (2003).
[15]. Q. Ma, P. Ryan, J. W. Freeland, and R. A. Rosenberg, Thermal Effect on the Oxides on Nb(100) Studied by Synchrotron-Radiation x-Ray Photoelectron Spectroscopy, Journal of Applied Physics 96, 7675 (2004).
[16]. E. M. Lechner, B. D. Oli, J. Makita, G. Ciovati, A. Gurevich, and M. Iavarone, Electron Tunneling and X-Ray Photoelectron Spectroscopy Studies of the Superconducting Properties of Nitrogen-Doped Niobium Resonator Cavities, Physical Review Applied 13, 044044 (2020).
[17]. J. Bardeen, L. N. Cooper, and J. R. Schrieffer, Theory of Superconductivity, Phys. Rev. 108, 1175 (1957).
[18]. G. B. Arnold, J. Zasadzinski, J. W. Osmun, and E. L. Wolf, Proximity Electron Tunneling Spectroscopy. II. Effects of the Induced N-Metal Pair Potential on Calculated S-Metal Properties, Journal of Low Temperature Physics 40, 225 (1980).
[19]. D. J. Trainer, B. Wang, F. Bobba, N. Samuelson, X. Xi, J. Zasadzinski, J. Nieminen, A. Bansil, and M. Iavarone, Proximity-Induced Superconductivity in Monolayer MoS₂, ACS Nano 14, 2718 (2020).
[20]. T. Kubo and A. Gurevich, Field-Dependent Nonlinear Surface Resistance and Its Optimization by Surface Nanostructuring in Superconductors, Physical Review B 100, 064522 (2019).
[21]. A. Gurevich and T. Kubo, Surface Impedance and Optimum Surface Resistance of a Superconductor with an Imperfect Surface, Physical Review B 96, 184515 (2017).
[22]. E. H. Brandt, The Flux-Line Lattice in Superconductors, Reports on Progress in Physics 58, 1465 (1995).
[23]. C. Caroli, P. G. De Gennes, and J. Matricon, Bound Fermion States on a Vortex Line in a Type II Superconductor, Physics Letters 9, 307 (1964).
[24]. Ch. Renner, A. D. Kent, Ph. Niedermann, Ø. Fischer, and F. Lévy, Scanning Tunneling Spectroscopy of a Vortex Core from the Clean to the Dirty Limit, Physical Review Letters 67, 1650 (1991).
[25]. G. Blatter, M. V. Feigel'man, V. B. Geshkenbein, A. I. Larkin, and V. M. Vinokur, Vortices in High-Temperature Superconductors, Reviews of Modern Physics 66, 1125 (1994).
[26]. V. S. Stolyarov, T. Cren, C. Brun, I. A. Golovchanskiy, O. V. Skryabina, D. I. Kasatonov, M. M. Khapaev, M. Yu. Kupriyanov, A. A. Golubov, and D. Roditchev, Expansion of a Superconducting Vortex Core into a Diffusive Metal, Nature Communications 9, 2277 (2018).
[27]. S. E. de Graaf, L. Faoro, L. B. Ioffe, S. Mahashabde, J. J. Burnett, T. Lindstrom, S. E. Kubatkin, A. V. Danilov, and A. Y. Tzalenchuk, Two-Level Systems in Superconducting Quantum Devices Due to Trapped Quasiparticles, Sci. Adv. 6, eabc5055 (2020).
[28]. M. Checchin, D. Frolov, A. Lunin, A. Grassellino, and A. Romanenko, Measurement of the Low-Temperature Loss Tangent of High-Resistivity Silicon Using a High-SQS Superconducting Resonator, Phys. Rev. Applied 18, 034013 (2022).
[29]. Bruno et al. Appl. Phys. Lett. 106, 182601 (2015).
[30]. Hines, Melissa A. Annual Review of Physical Chemistry; Palo Alto, 54, 29-56 (2003).

What is claimed is:

1. A device for quantum information technologies, comprising:
at least one hydrogen-passivated Si(111) (H:Si(111)) substrate, wherein Si(111) is a high resistivity silicon substrate.

2. The device of claim 1, wherein the at least one H:Si(111) substrate comprises a monohydride terminated silicon surface that is atomically well-defined with atomically flat terraces and sharp atomic steps.

3. The device of claim 2, further comprising at least one film of a material grown on the at least one H:Si (111) substrate, wherein the material comprises niobium (Nb), tantalum (Ta), aluminum (Al), titanium nitride (TiN), alloys of nitrides including NbN, TaN, NbTiN and/or TaTiN, and/or metalloid alloys including silicides, germanides and/or borides.

4. The device of claim 3, wherein the at least one film comprises at least one Nb film.

5. The device of claim 4, wherein the atomically-flat, monohydride H:Si(111) substrate yields a smoother and less defective interface between the at least one Nb film and the at least one H:Si(111) substrate.

6. The device of claim 4, wherein the at least one Nb film grown on the at least one H:Si(111) substrate presents more uniform superconducting properties and exhibit less quasiparticle broadening.

7. The device of claim 4, wherein the at least one Nb film has a thickness of about 30-40 nm that is sufficiently thin to remain sensitive to the Nb/Si interface while minimizing the suppression of the superconducting critical temperature (T_{c}) compared to the bulk Nb value.

8. The device of claim 4, wherein the out-of-plane lattice parameter is strained for the at least one film grown on the at least one H:Si(111) substrate with an expansion of about 0-3%.

9. The device of claim 4, wherein the at least one Nb film grown on the at least one H:Si(111) substrate shows granular growth with elongated and randomly oriented grains.

10. The device of claim 9, wherein the root mean square (RMS) roughness is in the order of about 1 nm.

11. The device of claim 4, wherein the tunneling spectrum on Nb—H:Si(111) shows higher coherence peaks and fewer states in the gap than the spectrum for Nb—Si(001).

12. The device of claim 3, being a transmon qubit device.

13. The device of claim 4, wherein the at least one Nb film grown on the H:Si(111) substrate has a reduced superconducting gap compared to a bulk Nb gap.

14. The device of claim 13, wherein the at least one Nb film grown on the at least one H:Si(111) substrate exhibits a spatial variation of the superconducting gap on a submicron scale.

15. The device of claim 13, wherein in the at least one Nb film grown on the at least one H:Si(111) substrate, the superconducting gap is spatially more uniform with the tunneling spectra showing a smaller quasiparticle broadening.

16. The device of claim 13, wherein the at least one Nb film grown on the at least one H:Si(111) substrate has a narrower distribution of gap values and much lower values of Γ/Δ₀, wherein Γ is the broadening parameter, and Δ₀ is the superconducting gap.

17. The device of claim 16, wherein Δ₀=1.32 meV for the at least one Nb film grown on the at least one H:Si(111) substrate.

18. The device of claim 13, wherein the tunneling spectrum on Nb—H:Si(111) has higher coherence peaks and fewer states in the gap than that on Nb—Si(001).

19. The device of claim 13, wherein the coherence peaks are suppressed at the center of the vortex core on a length scale given by the superconducting coherence length, and low-energy excitation Caroli-de Gennes-Matricon states are absent.

20. A method for fabricating a device for quantum information technologies, comprising:
providing at least one high resistivity silicon Si(111) substrate; and
performing hydrogen passivation on the at least one Si(111) substrate to form at least one hydrogen-passivated Si(111) (H:Si(111)) substrate.

21. The method of claim 20, wherein the at least one H:Si(111) substrate comprises a monohydride terminated silicon surface that is atomically well-defined with atomically flat terraces and sharp atomic steps.

22. The method of claim 20, wherein said performing the hydrogen passivation comprises a sequential treatment with hydrofluoric acid (HF) and ammonium fluoride (NH₄F).

23. The method of claim 22, wherein said performing the hydrogen passivation further comprises RCA (Radio Corporation of America) cleaning all components prior to HF and NH₄F treatment and extending the Ar-sparging time to at least two hours prior to the beginning of the surface treatment.

24. The method of claim 23, further comprising, immediately following the hydrogen passivation procedure, sealing the H:Si(111) substrate in ultra high purity (UHP) Ar to avoid oxidation of the H:Si(111) surface during transit to a deposition chamber.

25. The method of claim 24, further comprising growing at least one thin film of a material on the at least one H:Si(111) substrate in the deposition chamber, wherein the material comprises niobium (Nb), tantalum (Ta), aluminum (Al), titanium nitride (TiN), alloys of nitrides including NbN, TaN, NbTiN and/or TaTiN, and/or metalloid alloys including silicides, germanides and/or borides.

26. The method of claim 25, wherein the deposition chamber is a vacuum chamber with a base pressure<10⁻⁸ Torr at room temperature.

27. The method of claim 25, wherein the hydrogen passivation of the at least one Si(111) substrate minimizes oxidation and imperfections at the interface between the at least one H:Si(111) substrate and the at least one Nb thin film.

28. The method of claim 25, wherein the at least one Nb film grown on the at least one H:Si(111) substrate presents more uniform superconducting properties and exhibits less quasiparticle broadening.

29. The method of claim 25, wherein the at least one Nb film has a thickness of about 30-40 nm that is sufficiently thin to remain sensitive to the Nb/Si interface while minimizing the suppression of the superconducting critical temperature (T_{c}) compared to the bulk Nb value.

30. The method of claim 25, wherein the out-of-plane lattice parameter is strained for the at least one film grown on the at least one H:Si(111) substrate with an expansion of about 0-3%.

31. The method of claim 25, wherein the at least one Nb film grown on the at least one H:Si(111) substrate shows granular growth with elongated and randomly oriented grains.

32. The method of claim 31, wherein the root mean square (RMS) roughness is in the order of about 1 nm.

33. The method of claim 25, wherein the spectrum on Nb—H:Si(111) shows higher coherence peaks and fewer states in the gap than the spectrum for Nb—Si(001).

34. The method of claim 25, wherein the at least one Nb film grown on the H:Si(111) substrate has a reduced superconducting gap compared to a bulk Nb gap.

35. The method of claim 34, wherein the at least one Nb film grown on the at least one H:Si(111) substrate exhibits a spatial variation of the superconducting gap on a submicron scale.

36. The method of claim 34, wherein in the at least one Nb film grown on the at least one H:Si(111) substrate, the superconducting gap is spatially more uniform with the tunneling spectra showing a smaller quasiparticle broadening.

37. The method of claim 34, wherein the at least one Nb film grown on the at least one H:Si(111) substrate has a narrower distribution of gap values and much lower values of Γ/Δ₀, wherein Tis the broadening parameter, and Δ₀ is the superconducting gap.

38. The method of claim 37, wherein Δ₀=1.32 meV for the at least one Nb film grown on the at least one H:Si(111) substrate.

39. The method of claim 34, wherein the tunneling spectrum on Nb—H:Si (111) has higher coherence peaks and fewer states in the gap than that on Nb—Si(001).

40. The method of claim 34, wherein the coherence peaks are suppressed at the center of the vortex core on a length scale given by the superconducting coherence length, and low-energy excitation Caroli-de Gennes-Matricon states are absent.
